(19) United States
(12) Patent Application Publication
(10) Pub. No.: US 2006/0164128 A1
(43) Pub. Date: Jul. 27, 2006

(54) Low current power supply monitor circuit

(76) Inventors: Ira G. Miller, Tempe, AZ (US); Didier Salle, Toulouse (FR); Eduardo Velarde JR., Chandler, AZ (US)

Correspondence Address: INGRASSIA FISHER & LORENZ, P.C., 7150 E. CAMELBACK, STE. 325, SCOTTSDALE, AZ, 85251, US

(21) Appl. No.: 11/040,081

(22) Filed: Jan. 21, 2005

(51) Int. Cl. H03K 5/22

(52) U.S. Cl. 327/77

(57) ABSTRACT

A power supply monitor circuit is configured to monitor the state of a power supply, such as a battery, while drawing little power from the power supply and using relatively few device components and thus less on-chip resistance. The circuit includes a reference voltage circuit and a comparator circuit. The reference voltage circuit is adapted to receive a power supply voltage signal from the power supply and supplies a reference voltage signal having a voltage magnitude representative of the power supply voltage level. The comparator circuit receives the reference voltage signal from the voltage reference circuit and supplies an output signal having a voltage magnitude of either a first value or a second value, depending on the value of the reference voltage signal. The monitor circuit reduces the power supply voltage signal by about a bandgap, and the comparator circuit is implemented as a current mode bandgap circuit that merges the reference voltage with a comparator function.

### TECHNICAL FIELD

The present invention generally relates to power supply monitor circuit and, more particularly, to a power supply monitor circuit that draws a relatively low level of operational current.

### BACKGROUND

The operating voltage of many handheld devices, and myriad electronic circuits, is ever decreasing. In many instances these devices and circuits are powered using batteries. As is generally known, batteries deplete over time and, once depleted, must be replaced or recharged. Many battery-powered devices include some type of monitor circuit that monitors the state of charge of the battery (or batteries) powering the device, and alerts a user when the battery (or batteries) has depleted to a certain threshold. Many times this is determined by monitoring the voltage level of the battery.

The monitor circuits that are used to monitor the charge state of device batteries also draw current, and thus deplete the device batteries. As more and more devices use batteries as the power source, the need to provide longer lasting battery life will increase, and thus the power used by the electronic circuitry within the devices, including monitoring circuits, will also need to be lowered.

Accordingly, it is desirable to provide a circuit that will monitor the state of a power supply, such as a battery, while using as little power as possible. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawing figures, wherein like numerals denote like elements, and wherein:

FIG. 1 is a functional block diagram of a power supply voltage monitor circuit according to an embodiment of the present invention;

FIG. 2 is a schematic diagram of an exemplary reference voltage circuit that may be used to implement the circuit of FIG. 1.

FIG. 3 is a schematic diagram illustrating the power supply voltage monitor circuit of FIG. 1;

FIG. 4 is a schematic diagram of a current mirror circuit that may be used to implement the circuit of FIG. 1.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

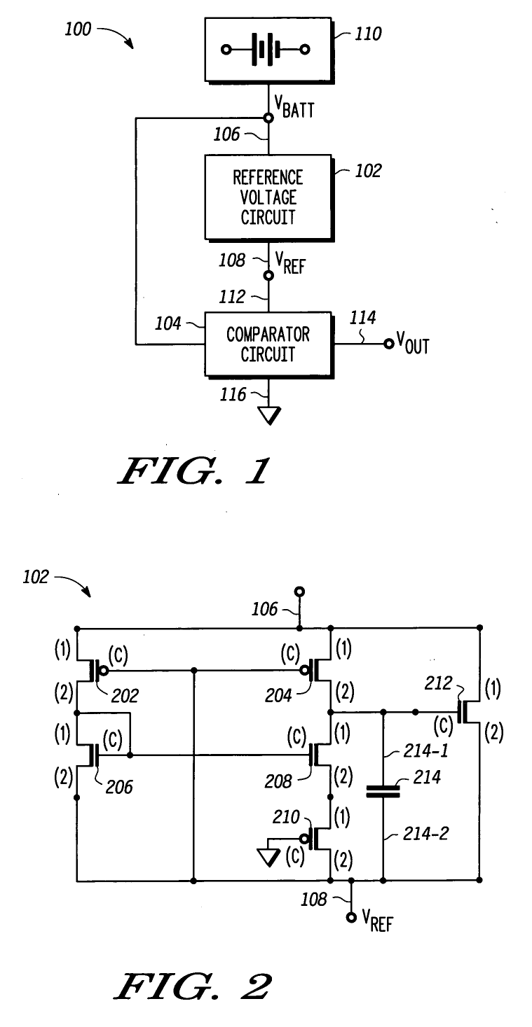

With reference now to FIG. 1, a functional block diagram of an embodiment of a power supply voltage monitor circuit 100 is shown. The circuit 100 includes a reference voltage circuit 102 and a comparator circuit 104. The reference voltage circuit 102 includes an input node 106 and an output node 108. The input node 106 is adapted to couple to a power supply 110, which in the depicted embodiment is a battery. When the input node 106 is so coupled, the reference voltage circuit 102 supplies a reference voltage signal (V_{ref}), via the output node 108, that has a voltage magnitude representative of the power supply voltage level (V_{batt}). It will be appreciated that the reference voltage circuit 102 may be implemented using any one of numerous circuit configurations, but is preferably implemented with a circuit that uses little power. An example of a particular preferred implementation is shown in FIG. 2, and will now be briefly described. Before doing so, however, it should be appreciated that the reference voltage circuit 102 depicted and described herein is more fully described in U.S. patent application Ser. No. 10/843,805, entitled “Circuit for Performing Voltage Regulation,” which is assigned to the assignee of the present application, and the entirety of which is hereby incorporated by reference.

Turning now to FIG. 2, the reference voltage circuit 102 includes a first transistor 202, a second transistor 204, a third transistor 206, a fourth transistor 208, a fifth transistor 210, a sixth transistor 212, and a capacitance circuit element 214. In the depicted embodiment, the transistors 202-212 each includes a first electrode (1), a second electrode (2), and a control electrode (C). The first, second, and fifth transistors 202, 204, and 210 are PMOS transistors, and the third, fourth, and fifth transistors 206, 208, 210 are NMOS transistors. The first electrodes (1) of first, second, and sixth transistors 202, 204, and 212 are all coupled to the voltage reference circuit input node 106. The control electrodes (C) of the first and second transistors 202, 204 are both coupled to the output node 108. The second electrode (2) of the first transistor 202 is coupled to the first electrode (1) and the control electrode (C) of the third transistor 206, and to the control electrode (C) of the fourth transistor 208. The second electrode (2) of the second transistor is coupled to the first electrode (1) of the fourth transistor 208, to the control electrode (C) of the sixth transistor 212, and to a first terminal 214-1 of the capacitance circuit element 214. The second electrode (2) of the fourth transistor 208 is coupled to the first electrode (1) of the fifth transistor 210. The control electrode (C) of the fifth transistor is coupled to a reference potential, such as ground, and the second electrode (2) of the fifth transistor 210 is coupled to the output node 108. The output node 108 is also coupled to the second electrode (2) of the third transistor, the second electrode (2) of the sixth transistor 212, and a second terminal 214-2 of the capacitance circuit element 214.

As is more fully described in the above mentioned prior U.S. Patent Application that is incorporated by reference, the areas of the first, second, third, fourth, and fifth transistors 202-210 may be adjusted so that the negative and positive temperature coefficients may be balanced. Moreover, the circuit 102 provides a relatively small voltage drop (i.e., approximately a bandgap) between the power supply voltage magnitude (V_{batt}) and the reference voltage magnitude (V_{ref}). It will be appreciated that the monitor circuit 100 could be implemented to include more than one reference voltage circuit 102, if so desired, to drop the power supply voltage magnitude (V_{batt}) further.

Returning now to FIG. 1, the comparator circuit 104 includes an input node 112, an output node 114, and a common node 116. The comparator circuit input node 112 is coupled to the reference voltage circuit output node 108, and is thus coupled to receive the reference voltage signal (V_{ref}). The comparator circuit 104, which is also described in more detail below, is configured, upon receipt of the reference voltage signal, to supply an output signal (Vₒᵤₜ) via the comparator circuit output node 114. In particular, the comparator circuit 104 is configured such that the output signal has a voltage magnitude of either a first value or a second value. More specifically, if the voltage magnitude of the reference voltage signal is greater than or equal to a predetermined value, then the output signal is the first value, and if the voltage magnitude of the reference voltage signal is less than the predetermined value, then the output signal is the second value. Although the specific and relative magnitudes of the first and second values may vary, in a particular embodiment, the first value is less than the second value.

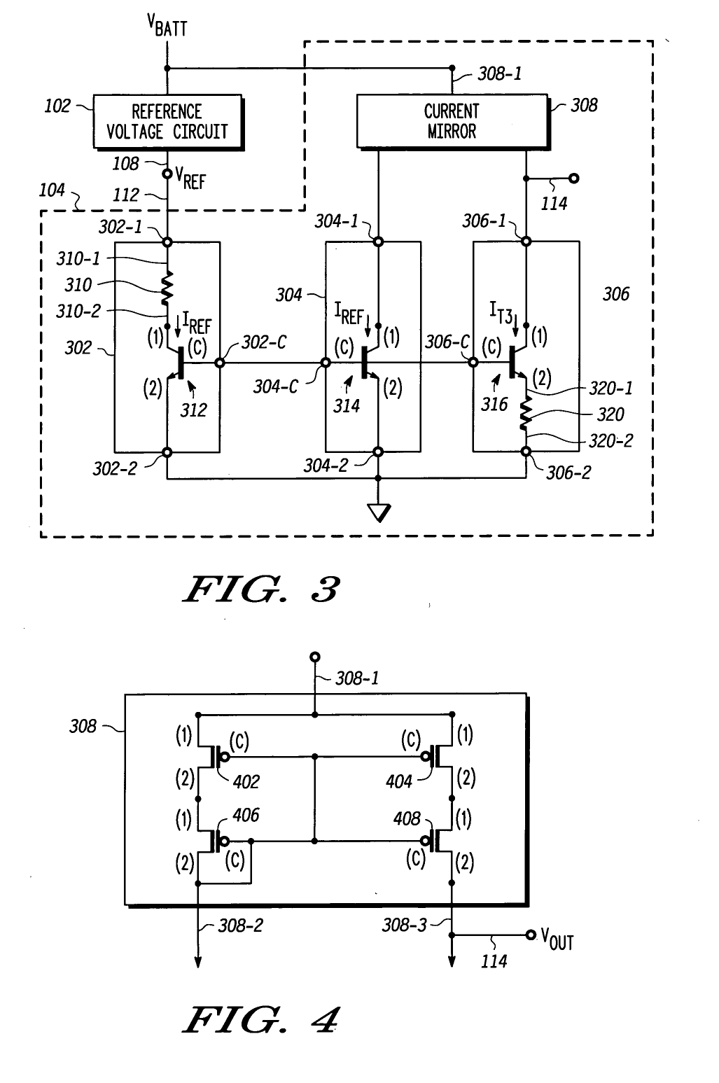

The comparator circuit 104 is shown in more detail in FIG. 3, which is a simplified schematic diagram of the power supply monitor circuit 100. As shown therein, the above described functionality is implemented using a first transistor circuit 302, a second transistor circuit 304, a third transistor circuit 306, and a current mirror circuit 308. The first transistor circuit 302 includes a first terminal 302-1, a second terminal 302-2, and a control terminal 302-C, and in the depicted embodiment is implemented using a resistor 310 and a first transistor 312. The second transistor circuit 304 also includes a first terminal 304-1, a second terminal 304-2, and a control terminal 304-C, and in the depicted embodiment is implemented as a second transistor 314. Similarly, the third transistor circuit 306 includes a terminal 306-1, a second terminal 306-2, and a control terminal 306-C, and in the depicted embodiment is implemented using a second resistor 320 and a third transistor 316.

Before proceeding further, it should be appreciated that although the first, second, and third transistors 312, 314, 316 are depicted as being implemented using bipolar transistors, and more specifically NPN transistors, one or more of these transistors could be implemented using PNP transistors, or MOS transistors. Moreover, although the resistors 310, 320 are depicted as being implemented using single, conventional resistor elements, either or both could be implemented using multiple conventional resistor elements, or one or more other types of circuit elements that exhibit a desired amount of resistance to the flow of DC current.

Returning once again to the description, it is seen that the first transistor circuit first terminal 302-1 is coupled to the comparator circuit input node 112, and thus receives the reference voltage signal therefrom, the first transistor circuit second terminal 302-2 is coupled to comparator circuit common node 116, and the first transistor circuit control terminal 302-C is coupled to the control terminals 304-C, 306-C of both the second and third transistor circuits 304, 306. The first transistor circuit 302 is configured such that a reference current (I_{ref}) flows through the first transistor circuit 302. As will now be explained, the magnitude of the reference current that flows through the first transistor circuit 302 is proportional to the voltage magnitude of the reference voltage signal.

The first transistor 312 includes a first electrode 312(1), a second electrode 312(2), and a control electrode 312(C), and the first resistor 310 includes a first terminal 310-1 and a second terminal 310-2. The resistor first terminal 310-1 is coupled to the comparator circuit input node 112, and the resistor second terminal 310-2 is coupled to the first transistor first electrode 312(1). The first transistor first electrode 312(1) is in turn coupled to the control electrode 312(C), and the second electrode 312(2) is coupled to the comparator circuit common node 118. With this configuration, the magnitude of the current flow through the first transistor circuit 302 is given by:

$${I}_{ref} = \frac{{V}_{ref} - {V}_{be1}}{R1}$$

where V_{be1} is the base-to-emitter voltage of the first transistor 312, and R1 is the resistance value of the first resistor 310.

Turning now to the second transistor circuit 304, it is seen that its first terminal 304-1 is coupled to the current mirror circuit 308, its second terminal 304-2 is coupled to the comparator circuit common node 116, and as was noted above its control terminal 304-C is coupled to the first transistor circuit control terminal 302-C. The second transistor circuit 304 is configured such that the current flow through it has a magnitude that is substantially equal to the reference current (I_{ref}). The manner in which the second transistor circuit 304 is implemented in order to achieve this functionality will now be described.

As was noted above, the second transistor circuit 304, at least in the depicted embodiment, includes just the second transistor 314. It will be appreciated, however, that in other embodiments the second transistor circuit 304 could include additional components. Nonetheless, the second transistor 314, like the first transistor 312, includes a first electrode 314(1), a second electrode 314(2) and a control electrode 314(C). The second transistor control electrode 314(C), as was alluded to above, is coupled to the first transistor circuit control terminal 302-C, and thus to the first transistor control electrode 312(C). As FIG. 3 also shows, the second transistor first electrode 314(1) is coupled to the current mirror circuit 308, and the second transistor second electrode 314(2) is coupled to comparator circuit common node 116. With this configuration, the current flow through the second transistor circuit 304 will mirror the reference current flow through the first transistor circuit 302. As is generally known, with this circuit configuration the magnitude of the current flow through the second transistor circuit 304 will depend, at least in part, on the emitter ratio of the second and first transistors 314, 312. In the preferred embodiment, the ratio is 1:1, and thus, as FIG. 3 illustrates, the magnitude of the current flow through the second transistor circuit 304, which is supplied from the current mirror circuit 308, is also (I_{ref}).

The third transistor circuit 306 is coupled to the first transistor circuit 302, the second transistor circuit 304, the current mirror circuit 308, and the comparator circuit common node 116. Specifically, the third transistor circuit first terminal 306-1 is coupled to the current mirror circuit 308, the transistor circuit second terminal 306-2 is coupled to the comparator circuit common node 116, and the third transistor circuit control terminal 316-C is coupled to the first and second transistor circuit control terminals 302-C, 304-C. The third transistor circuit 306 is configured such that the current flow through it has a magnitude (I_{T3}) that is based, at least in part, on the reference current magnitude (I_{ref}). A particular preferred circuit configuration that provides this functionality will now be described.

As was noted above, the third transistor circuit 306 includes the third transistor 316 and the second resistor 320. Like the first and second transistors 312, 314, the third transistor 316 includes a first electrode 316(1), a second electrode 316(2), and a control electrode 316(C), and like the first resistor 310, the second resistor 320 includes a first terminal 320-1 and a second terminal 320-2. The third transistor first electrode 316(1) is coupled to the current mirror circuit 308, the third transistor control electrode 316(C) is coupled to the first and second transistor control terminals 302-C, 304-C, the third transistor second electrode 316(2) is coupled to the second resistor first terminal 320-1, and the second resistor second terminal 320-2 is coupled to the comparator circuit common node 116. Unlike the second transistor 314, the third transistor 316 has an emitter area that is larger than that of the first transistor 312, and thus the emitter ratio is N:1, where N is an integer larger than one. Because the emitter area ratio is larger than one, the base-to-emitter voltage (V_{be1}) of the first transistor 312, will be larger than the base-to-emitter voltage(V_{be3}) of the third transistor 316, and the magnitude of the current flow (I_{T3}) through the third transistor circuit 306 is given by:

$${I}_{T3} = \frac{Δ {V}_{be}}{R2}$$

where R2 is the resistance value of the second resistor 320, and ΔV_{be} is given by:
ΔV_{be}=V_{be1}−V_{be3}
where V_{be1} is the base-to-emitter voltage of the first transistor 312, and V_{be3} is the base-to-emitter voltage of the third transistor 316. As with the second transistor circuit 304, the current (I_{T3}) that flows through the third transistor circuit 306 is supplied from the current mirror circuit 308, which will now be briefly described.

The current mirror circuit 308 may be implemented using any one of numerous current mirror circuit configurations. In the depicted embodiment, the current mirror circuit 308 includes a power supply terminal 308-1 and two current supply terminals—a first current supply terminal 308-2 and a second current supply terminal 308-3. The power supply terminal 308-1 is adapted to couple to a source of electrical power, such as the power supply 110, and the first and second current supply terminals 308-2, 308-3 are coupled to the second and third transistor circuits 304, 306, respectively, and supply current thereto. The second current supply terminal 308-3 also supplies the output signal (Vₒᵤₜ) to the comparator circuit output node 114.

A particular physical implementation of the current mirror circuit 308 is shown in FIG. 4, and with reference thereto will now be described in more detail. The exemplary current mirror circuit 308 includes four transistors—a first transistor 402, a second transistor 404, a third transistor 406, and a fourth transistor 408—each with a first electrode (1), a second electrode (2), and a control electrode (C). In the depicted embodiment, the transistors 402-408 are all PMOS transistors, though it will be appreciated that this is merely exemplary and that other transistor types and configurations could be used. It will additionally be appreciated that four transistors is merely exemplary of a particular embodiment, and that the current mirror circuit 308 could be implemented with more or less than this number of transistors. Nonetheless, in the depicted embodiment, the first electrodes (1) of the first and second transistors 402, 404 are coupled to the comparator circuit power supply node 308-1. The second electrodes (2) of the first and second transistors 402, 404 are coupled to the first electrodes (1) of the third and fourth transistors 406, 408, respectively, and the second electrodes of the third and fourth transistors 406, 408 function as the comparator circuit first and second current supply terminals 308-1, 308-2, respectively. The control electrodes (C) of the first, second, third, and fourth transistors 402-408 are all coupled to the second electrode (2) of the third transistor 406 (e.g., the comparator circuit first current supply terminal 308-1).

Returning once again to FIG. 3, the output signal at the comparator circuit output node 114 has a voltage magnitude of either a first value or a second value. As was noted above, if the voltage magnitude of the reference voltage signal is greater than or equal to a predetermined value, then the output signal is the first value, and if the voltage magnitude of the reference voltage signal is less than the predetermined value, then the output signal is the second value that is less than the first value. More specifically, if the magnitude of the reference current flow is greater than or equal to the current flow through the third transistor circuit 306 (e.g., I_{ref}≧I_{T3}), then the output signal is the first value. Conversely, if the magnitude of the reference current is less than the current flow through the third transistor circuit 306 (e.g., I_{ref}<I_{T3}), then the output signal is the second value. This is because the current flow (I_{T3}) through the third transistor circuit 306 pulls down the comparator circuit output node 114, whereas the current flow (I_{ref}) through second transistor circuit 304 pulls up the comparator circuit output node 114.

It may thus be seen that the “trip point” of the comparator circuit 104 occurs when the reference current (I_{ref}) equals the current (I_{T3}) through the third transistor circuit 304. Using the previous equations that define I_{ref} and I_{T3}, and substituting as appropriate, it follows that the comparator circuit trip point occurs in accordance with the following equation:

$${V}_{trip} = {V}_{be1} + Δ {V}_{be} ( \frac{R1}{R2} )$$

where Vₜᵣᵢₚ is the value of V_{ref} at the trip point.

From the above it is seen that the trip point occurs when the voltage magnitude of the power supply reaches the reference voltage trip point (Vₜᵣᵢₚ) plus the voltage drop across the reference voltage circuit 102. As was noted above, in the depicted embodiment the voltage drop across the reference voltage circuit 102 is approximately a bandgap. Moreover, the comparator circuit 104 is configured such that the reference voltage trip point (Vₜᵣᵢₚ) is approximately a bandgap. Thus, the power supply monitor circuit 100 uses relatively little power as compared to many current monitor circuits. For example, in the depicted embodiment the power supply monitor circuit 100 uses about ⅓ of the power as compared to many conventional current monitors. Moreover, the power supply monitor circuit 100 may be implemented with significantly fewer devices than many conventional monitor circuits, and thus uses much less area of a die, and thus utilizes much less on-chip resistance. For example, many conventional monitor circuits are implemented with more than thirty circuit devices and with on-chip resistances of at least 50 Mega-ohms, whereas the circuit described herein can be implemented with as little as fourteen circuit devices with an on-chip resistance of about 6.5 Mega-ohms.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A circuit for monitoring power supply voltage level, comprising:
a reference voltage circuit adapted to receive a power supply voltage signal and configured, upon receipt thereof, to supply a reference voltage signal having a voltage magnitude representative of the power supply voltage level; and
a comparator circuit having at least an output node and a common node, the comparator circuit coupled to receive the reference voltage signal from the voltage reference circuit and configured, upon receipt thereof, to supply an output signal having a voltage magnitude of either a first value or a second value to the output node, the comparator circuit including:
a first transistor circuit having a first terminal, a second terminal, and a control terminal, the first transistor circuit first terminal coupled to receive the reference voltage signal, and the first transistor second terminal coupled to the common node, whereby a reference current, having a current magnitude proportional to the reference voltage signal voltage magnitude, flows through the first transistor circuit,
a second transistor circuit having a first terminal, a second terminal, and a control terminal, the second transistor circuit second terminal coupled to the common node, and the second transistor circuit control terminal coupled to the first transistor circuit control terminal, the second transistor circuit configured such that current flow therethrough is substantially equal in magnitude to the reference current magnitude,
a third transistor circuit having a first terminal, a second terminal, and a control terminal, the third transistor circuit first terminal coupled to the output node, the third transistor circuit second terminal coupled to the common node, and the third transistor circuit control terminal coupled to the first transistor circuit control terminal, the third transistor circuit configured such that current flow therethrough has a magnitude that is based at least in part on the reference current magnitude, and
a current mirror circuit having first and second current supply terminals coupled to the second transistor circuit first terminal and to the third transistor circuit first terminal, respectively, the current mirror circuit configured to supply current to the second and third transistor circuits.

2. The circuit of claim 1, wherein:
the voltage magnitude of the output signal is the first value when the reference current magnitude is greater than or equal to the current flow through the third transistor circuit; and
the voltage magnitude of the output signal is the second value when the reference current magnitude is less than the current flow through the third transistor circuit.

3. The circuit of claim 1, wherein:
the reference current magnitude is greater than or equal to the current flow through the third transistor circuit when the reference voltage is greater than or equal to a predetermined value; and
the reference current magnitude is less than the current flow through the third transistor circuit when the reference voltage is less than the predetermined value.

4. The circuit of claim 1, wherein the first transistor circuit comprises:
a transistor having a first electrode, a second electrode, and a control electrode, the first electrode coupled to the control electrode, the second electrode coupled to the common node; and
a resistor having a first terminal and a second terminal, the resistor first terminal coupled to receive the reference voltage signal, the resistor second terminal coupled to the transistor first electrode.

5. The circuit of claim 4, wherein the transistor is bipolar transistor.

6. The circuit of claim 5, wherein the bipolar transistor is an NPN transistor.

7. The circuit of claim 1, wherein the third transistor circuit comprises:
a transistor having a first electrode, a second electrode, and a control electrode, the transistor first electrode coupled to the output node, the transistor control electrode coupled to the first transistor circuit control terminal; and
a resistor having a first terminal and a second terminal, the resistor first terminal coupled to the transistor second electrode, the resistor second electrode coupled to the common node.

8. The circuit of claim 7, wherein the transistor is bipolar transistor.

9. The circuit of claim 8, wherein the bipolar transistor is an NPN transistor.

10. The circuit of claim 1, wherein the second transistor circuit comprises:
a transistor having a first electrode, a second electrode, and a control electrode, the transistor first electrode coupled to the current mirror, the transistor second electrode coupled to the common node, the transistor control electrode coupled to the first transistor circuit control terminal.

11. The circuit of claim 10, wherein the transistor is bipolar transistor.

12. The circuit of claim 1 1, wherein the bipolar transistor is an NPN transistor.

13. The circuit of claim 1, wherein the current mirror circuit comprises:
a first transistor having a first electrode, a second electrode, and a control electrode, the first transistor first electrode adapted to couple to a voltage source, and the first transistor second electrode and the first transistor control electrode both coupled to the second transistor circuit first terminal; and
a second transistor having a first electrode, a second electrode, and a control electrode, the second transistor first electrode adapted to couple to a voltage source, the second transistor second electrode coupled to the output node, and the second transistor control electrode coupled to the first transistor control electrode.

14. The circuit of claim 13, wherein the current mirror circuit further comprises:
a third transistor having a first electrode, a second electrode, and a control electrode, the third transistor first electrode adapted to couple to a voltage source, and the third transistor second electrode coupled to the first transistor circuit first electrode, and the third transistor control electrode coupled to the first transistor control electrode; and
a fourth transistor having a first electrode, a second electrode, and a control electrode, the fourth transistor first electrode adapted to couple to a voltage source, the fourth transistor second electrode coupled to the second transistor first electrode, and the fourth transistor control electrode coupled to the third transistor control electrode.

15. The circuit of claim 1, wherein the reference voltage circuit is configured such that the voltage magnitude of the reference voltage signal is approximately equal to the power supply voltage level less a transistor bandgap voltage.

16. A comparator circuit, comprising:
a current mirror circuit having at least a first current supply terminal and a second current supply terminal;
a first resistor having a first terminal and a second terminal, the resistor first terminal adapted to couple to a voltage source having a voltage magnitude;
a first transistor having a first electrode, a second electrode, and a control electrode, the first transistor first electrode coupled to the first resistor second terminal, the first transistor second electrode coupled to a common node, and the first transistor control electrode coupled to the first transistor first electrode, whereby a reference current, having a current magnitude proportional to the voltage magnitude of the voltage source, flows through the first transistor circuit;
a second transistor having a first electrode, a second electrode, and a control electrode, the second transistor first electrode coupled to the current mirror circuit first current supply terminal, the second transistor second electrode coupled to the first transistor second electrode, the second transistor control electrode coupled to the first transistor control electrode, the second transistor configured such that current flow therethrough is substantially equal in magnitude to the reference current magnitude;
a third transistor having a first electrode, a second electrode, and a control electrode, the third transistor first electrode coupled to the current mirror circuit second current supply terminal, the third transistor control electrode coupled to the first transistor control electrode, the third transistor configured such that current flow therethrough has a magnitude that is based at least in part on the reference current magnitude; and
a second resistor having a first terminal and a second terminal, the second resistor first terminal coupled to the third transistor second electrode, the second resistor second electrode coupled to the first transistor second electrode,
wherein the third transistor first electrode is at a voltage magnitude of (i) a first value when the reference current magnitude is greater than the magnitude of the current flow through the third transistor and (ii) a second value when the reference current magnitude is less than the magnitude of the current flow through the third transistor.

17. The circuit of claim 1, wherein:
the reference current magnitude is greater than or equal to the current flow through the third transistor circuit when the voltage magnitude is greater than or equal to a predetermined value; and
the reference current magnitude is less than the current flow through the third transistor circuit when the voltage magnitude is less than the predetermined value.

18. The circuit of claim 16, wherein the first, second, and third transistors are bipolar transistors.

19. The circuit of claim 18, wherein the bipolar transistors are each NPN transistors.

20. The circuit of claim 16, wherein the current mirror circuit comprises:
a fourth transistor having a first electrode, a second electrode, and a control electrode, the fourth transistor first electrode adapted to couple to a voltage source, and the fourth transistor second electrode and the fourth transistor control electrode both coupled to the second transistor first electrode; and
a fifth transistor having a first electrode, a second electrode, and a control electrode, the fifth transistor first electrode adapted to couple to a voltage source, the fifth transistor second electrode coupled to the third transistor first electrode, and the fifth transistor control electrode coupled to the fourth transistor control electrode.

21. The circuit of claim 16, wherein the fourth and fifth transistors are MOS transistors.

22. The circuit of claim 21, wherein the MOS transistors are PMOS transistors.

23. The circuit of claim 22, wherein the current mirror circuit further comprises:
a sixth transistor having a first electrode, a second electrode, and a control electrode, the sixth transistor first electrode adapted to couple to a voltage source, and the sixth transistor second electrode coupled to the fourth transistor first electrode, and the sixth transistor control electrode coupled to the fourth transistor control electrode; and
a seventh transistor having a first electrode, a second electrode, and a control electrode, the seventh transistor first electrode adapted to couple to a voltage source, the seventh transistor second electrode coupled to the fifth transistor first electrode, and the seventh transistor control electrode coupled to the sixth transistor control electrode.

24. The circuit of claim 16, wherein the sixth and seventh transistors are MOS transistors.

25. The circuit of claim 24, wherein the MOS transistors are PMOS transistors.
